(19) United States
(12) Patent Application Publication
(10) Pub. No.: US 2006/0084200 A1
(43) Pub. Date: Apr. 20, 2006

(54) Individually adaptable device surface

(75) Inventors: Fritz Breimesser, Nurnberg (DE); Jorg Hassel, Erlangen (DE); Ingeborg Lades, Erlangen (DE)

Correspondence Address: SIEMENS CORPORATION;INTELLECTUAL PROPERTY DEPARTMENT, 170 WOOD AVENUE, SOUTH, ISELIN, NJ, 08830, US

(73) Assignee: SIEMENS AKTIENGESELLSCHAFT

(21) Appl. No.: 11/253,250

(22) Filed: Oct. 18, 2005

(30) Foreign Application Priority Data
Oct. 19, 2004 (DE) 10 2004 050 904.2

(51) Int. Cl. H01L 21/50

(52) U.S. Cl. 438/106; 257/100

(57) ABSTRACT

The invention relates to device with electronic component which covers at least a part of a surface of the device. In order, even with large-scale mass production of a device, to allow the greatest possible individualization there is provision for the electronic component to feature both a number of switch elements and also a number of light elements for surface design. The light elements enable the appearance of the surface of the device to be designed in accordance with user wishes.

### CROSS REFERENCE TO RELATED APPLICATIONS

This application claims priority to the German application No. 10 2004 050 904.2, filed Oct. 19, 2004 and which is incorporated by reference herein in its entirety.

### FIELD OF INVENTION

The invention relates to device with electronic component which covers at least a part of the surface of the device.

### SUMMARY OF THE INVENTION

A significant role in the decision to buy consumer goods in both the private and industrial sector is played by the extent to which users can adapt the device to meet their individual requirements. One of the areas to which this relates is the user interface. On the other hand however the appearance and the color scheme of the device have an ever greater role to play.

One object of the invention is to provide a device which, even with large-scale series production, enables the device to be tailored as much as possible to the individual requirements of the user. This object is achieved by the claims.

In accordance with the invention there is provision in this case for the device to feature an electronic component which constitutes at least a part of one surface of the device and features both a number of switching elements and also a number of light elements. This not only makes it possible to adapt the user interface to the desires of the user. The light elements enable the appearance of the surface of the device to be designed in accordance with user wishes. If the electronic component is provided covering the entire surface of the device or at least significant parts thereof, practically the entire outer surface of the device can be adapted to the wishes of the user. The device can be given a particular color scheme, for example in the “house colors” of the manufacturer, product or manufacturer names or -logos and such like can also can be incorporated with the aid of the light elements. In other words an individualization of each single device is possible to the extent where both large-scale and small-scale series products as well as individual items are given an individual design. At the same time there are no technical differences between the devices used. All devices are identical and originate from a single production process. However every single one of these devices can still be individually adapted with the aid of the light elements.

The present invention can be used for consumer goods, for example in mobile telephones, video consoles or any other devices. Another area of application is industrial devices, for example operator terminals of automation devices, parts of machines or machines themselves.

As well as a degree of uniform coloring of the surface of a device specific patterns can also be embodied on the surface for example. Thus for example it is conceivable when the invention is used for mobile telephones to present a specific design of a casing shell by providing an appropriate electronic component. In other words not only ring tones but also casing designs can then be chosen and used in accordance with the user's individual tastes. In addition to merely coloring or displaying a pattern on the device there is also the option of displaying the device status of the mobile telephone by changing the surface of the telephone. For example, with a mobile telephone which is equipped with such an electronic component, the color of the telephone casing can change for an incoming call or the entire telephone casing can start to flash for an incoming call. Similar applications are also conceivable for industrial terminals. Thus the electronic components can for example be connected to the fault detection-system on a device, so that for example a faulty component of a machine, an industrial system or a computer system which has failed or is likely to fail within a short time can be made to flash over its entire surface or make itself noticeable in some other way.

Advantageous embodiments of the invention are specified in the dependent claims.

It is accordingly especially advantageous for the electronic component to feature a control module. The control module is embodied to control the switching and light elements. It is preferably connected to a memory module which is used to store a number of surface patterns or other designs. The stored patterns can for example be a “basic set” supplied by the manufacturer of the device. In addition the memory module can also store a number of further patterns or designs. It is very greatly advantageous in this context for the electronic components to be connected via an interface to an external pattern source. This can for example involve an interface to a computer network, for example to the Internet, so that patterns can be downloaded from a manufacturer's Internet site or Internet sites of other providers or can be copied into the memory module.

The design used can in this case be individually selected by the user and changed at any time. In this case not only the patterns stored in the memory but also patterns derived from these can preferably be used. Thus for example two or more patterns can be combined with each other. Such a combination can especially consist of “mixing” two different designs by overlaying them. On the other hand it is also possible for example for the front shell of a mobile telephone to be provided with a first pattern and the rear shell of the mobile telephone to be provided with a second pattern. The term “pattern” here is taken to mean not only decorations but any type of coloring.

The use of a polymer-based electronic component is especially advantageous. Organic light emitting diodes (OLED) are especially used as light elements for the design of the surface. Compared to expensive coating or etching technologies based on conventional semiconductors, these types of electronic circuit can be produced with relatively simple printing processes. This type of polymer electronics allows very precise and also very low-cost mass production by printing the electronics onto the surface of the device using screen, tampon, offset, gravure or inkjet printing or microcontact printing. Preferably all the elements of the electronic component are embodied in this technology.

An exemplary embodiment of the present invention is described in more detail below.

### BRIEF DESCRIPTION OF THE DRAWINGS

FIG. 1 shows a cross-section through one surface of a mobile telephone,

FIG. 2 shows an overhead view of a mobile telephone, and

FIG. 3 shows a further overhead view of a mobile telephone.

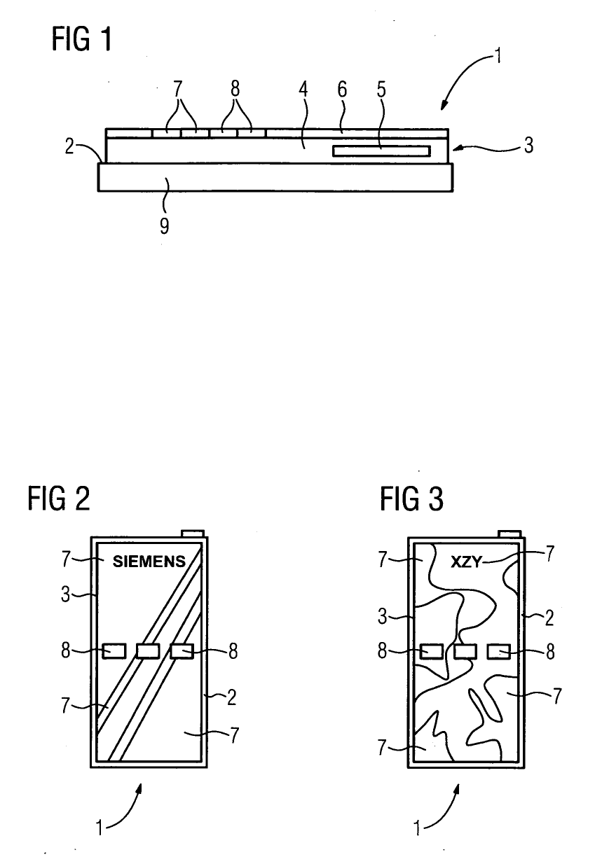

### DETAILED DESCRIPTION OF THE INVENTION

A mobile telephone 1 features an electronic component 3 on its front side 2. The electronic component 3 essentially consists of control electronics 4 with a memory element 5 and a light-emitting layer 6 applied to the control electronics 4 with symbolically represented OLEDs 7 and switch elements 8. In this case the entire electronic component 3 is manufactured on a polymer basis and printed onto the casing 9 of the mobile telephone 1. Via an interface (not shown), integrated into the control electronics 3, different patterns or designs can be loaded from an external source (not shown) into the memory element 5. The mobile telephone 1 is operated via the switch elements 8 shown on its surface. The same switch elements 8 are also used to operate the control electronics 3.

FIG. 2 shows a symbolic overhead view of the front 2 of the mobile telephone 1 with integrated electronic component 3. Almost the entire front shell of the mobile telephone 1 is embodied here as a controllable surface. In this case the usual controls of a mobile telephone 1 are embodied as switch elements 8 of the electronic component 3, whereas the entire remaining surface is formed from light elements 7 which allow the surface design to be changed. Thus for example simply loading a new pattern makes it possible to change the appearance of the mobile telephone 1 from the form shown in FIG. 2 to the form shown in FIG. 3.

The switch elements 8, also implemented in polymer technology, are preferably embodied as touch switches. The functional principle used (electrostatic, resonance magnetism etc.) can vary depending on application.

1.-4. (canceled)

5. A device comprising a surface covered at least partly by an electronic component, wherein the electronic component has a number of switch elements for operating the device and a number of light elements for designing the appearance of the surface.

6. The device in accordance with claim 5, wherein the electronic component has a control module.

7. The device in accordance with claim 5, wherein the electronic component has a memory module.

8. The device in accordance with claim 5, wherein the electronic component has a memory module.

9. The device in accordance with claim 5, wherein the electronic component is a polymer-based electronic component.

10. The device in accordance with claim 6, wherein the electronic component is a polymer-based electronic component.

11. The device in accordance with claim 7, wherein the electronic component is a polymer-based electronic component.

12. The device in accordance with claim 8, wherein the electronic component is a polymer-based electronic component.

13. The device in accordance with claim 5, wherein the light elements are diodes.

14. A device with a surface which is sheeted at least partly by an electronic component, with the electronic component featuring at least one switch element for operating the device and at least one diode for configuring the appearance of the surface.

15. The device in accordance with claim 14, wherein the electronic component comprises a control module.

16. The device in accordance with claim 14, wherein the electronic component comprises a memory module.

17. The device in accordance with claim 14, wherein the electronic component is polymer-based.
